(19) United States
(12) Patent Application Publication
(10) Pub. No.: US 2026/0367043 A1
(43) Pub. Date: Nov. 19, 2026

(54) HIGH-SENSITIVITY AND HIGH-BANDWIDTH SINGLE-RESONANCE TRANSPARENT ULTRASONIC TRANSDUCER AND MANUFACTURING METHOD THEREFOR

(71) Applicant: POSTECH RESEARCH AND BUSINESS DEVELOPMENT FOUNDATION, Pohang-si, Gyeongsangbuk-do (KR)

(72) Inventors: Chul Hong KIM, Pohang-si, Gyeongsangbuk-do (KR); Min Su KIM, Pohang-si, Gyeongsangbuk-do (KR); Hyung Ham KIM, Pohang-si, Gyeongsangbuk-do (KR); Seong Hee CHO, Pohang-si, Gyeongsangbuk-do (KR)

(21) Appl. No.: 19/126,512

(22) PCT Filed: Oct. 5, 2023
(86) PCT No.: PCT/KR2023/015361

§ 371 Date: May 1, 2025

(30) Foreign Application Priority Data
Nov. 1, 2022 (KR) 10-2022-0143894

(51) Int. Cl. G01N 29/24

(52) U.S. Cl. CPC G01N 29/2437

(57) ABSTRACT

Disclosed are a transparent ultrasonic transducer capable of maximizing ultrasonic transmission and reception efficiency while maintaining a high degree of optical transparency, and a manufacturing method therefor. The transparent ultrasonic transducer comprises: a thin film-type piezoelectric unit for generating vibration in response to an electrical signal, or generating an electrical signal in response to vibration; a frontal matching layer formed, on the front of the piezoelectric unit, from a composite material that is freely shaped in a liquid or clay-like mixture form without matching gaps; and a sound-absorbing layer arranged on the rear of the piezoelectric unit.

### TECHNICAL FIELD

The present disclosure relates to a transparent ultrasound transducer capable of maximizing ultrasonic transceiving efficiency while maintaining high optical transparency, and a method for fabricating the transducer.

### BACKGROUND ART

In general, an ultrasound transducer used in an ultrasonic sensor includes a piezoelectric layer generating vibrations upon receiving an electrical signal from a pair of electrodes and reflecting acoustic waves at the front and back boundaries to amplify the intensity of the acoustic waves within the space between the boundaries, a matching layer properly impeding vibration emission to facilitate the acoustic waves amplification within the piezoelectric layer while emitting the amplified acoustic waves vibrations from the front of the piezoelectric layer, and an acoustic absorption layer absorbing energy that radiates from the back of the piezoelectric layer and controlling backward-emitting energy ratio to control the temporal response length of the device.

To improve the performance of the ultrasound transducer, it is important that the piezoelectric layer has even reflectivity over a wide frequency bandwidth while having adequate reflectivity at the boundaries with the matching layer and the acoustic absorption layer.

The performance required of the matching layer and the acoustic absorption layer of the ultrasound transducer, based on a ceramic piezoelectric material, is as follows. In the case of dual matching layers, the acoustic impedance of the first matching layer is 7 to 9 megarayls (MRayl) and the acoustic impedance of the second matching layer is 2 to 3 MRayl. In the case of triple matching layers, the acoustic impedance of the first matching layer is 10 to 11 MRayl, the acoustic impedance of the middle matching layer is 3 to 5 MRayl, and the acoustic impedance of the second matching layer is 2 to 3 MRayl. Further, the acoustic impedance of the acoustic absorption layer is 4 to 8 MRayl. In addition, the acoustic impedance of a piezoelectric material of the ultrasound transducer is usually 30 to 35 MRayl, which is intended for using the vibrations of the piezoelectric material in water or living tissues having about 1.5 to 1.6 MRayl.

On the other hand, a transparent material having acoustic performance suitable for ultrasound transducers is not yet known. Methods for bonding glass to a matching layer have been tried to improve the acoustic performance in the conventional opaque ultrasound transducers, but the acoustic impedance of glass is 12 to 15 MRayl, which is inappropriate for the impedance required of the ultrasound transducers, so there is a limit restricting the improvement of acoustic performance, and there is an issue of impedance reversal caused by an adhesive when bonding glass.

In addition, no material having an acoustic impedance of 4 to 10 MRayl exists in nature. Therefore, in forming a matching layer or an acoustic absorption layer of conventional opaque transducers, metals or ceramics having a relatively high acoustic impedance have been used with polymer materials having a relatively low acoustic impedance to control the acoustic impedance.

For example, a method for applying a low-viscosity adhesive and bonding in a pressurized environment was used to control the acoustic impedance in fabricating an opaque low-frequency transducer operating at 5 MHz or less, allowing a gap of about 0.5 mills between the piezoelectric layer and the matching layer or between the piezoelectric layer and the acoustic absorption layer.

Further, a method for applying a liquid or clay-like mixture, prepared by mixing powder of a material having a high acoustic impedance into a liquid of a polymer material before curing or before polymerization, to the piezoelectric element surface to cure and then cutting the cured mixture to a target thickness was used in fabricating most conventional opaque ultrasound transducers that allow no bonding gap to ensure performance.

However, a transparent ultrasound transducer fabricated by conventional methods has an issue of impedance mismatch, and due to technical limitations in implementation, it is difficult to form a matching layer having a thickness of ¼ wavelength or less, so a thickness of more than 20 times the wavelength is used or a material having an acoustic impedance as low as 4 megarayls at most is used as the matching layer.

So, there is a need for a new configuration approach for a transparent ultrasound transducer having performance at least similar to that of an opaque ultrasound transducer.

### DISCLOSURE

### Technical Problem

The present disclosure has been devised to overcome the limitations of the above-described prior art. An object of the present disclosure is to provide a transparent ultrasound transducer and a method for manufacturing the same, which improve the acoustic characteristics of the transducer to achieve ultrasonic transmission and reception performance equivalent to that of conventional opaque ultrasonic transducers, while also exhibiting high sensitivity, wide bandwidth, and single-resonance characteristics.

Another object of the present disclosure is to provide a transparent ultrasound transducer and a method for manufacturing the same, which maximize ultrasonic transmission and reception efficiency while maintaining high optical transparency, thereby simultaneously satisfying both acoustic and optical characteristics and enabling the transducer to exhibit near-theoretical maximum acoustic performance.

Still another object of the present disclosure is to provide a transparent ultrasound transducer and a method for manufacturing the same, which maintain optical transparency while optimizing ultrasonic back attenuation, thereby enabling appropriate control of the frequency response characteristics of the ultrasonic transducer.

### Technical Solution

According to an aspect of the present disclosure for solving the above technical problem, a transparent ultrasound transducer may comprise: a piezoelectric unit generating vibrations in response to an electrical signal or generating electrical signals in response to vibrations; a front matching layer formed in front of the piezoelectric unit from a composite material in a liquid or clay-like mixture form, allowing free molding without a bonding gap; and an acoustic absorption layer disposed on the back of the piezoelectric unit.

The acoustic absorption layer may comprise a back matching layer formed from a composite material on the back of the piezoelectric unit and a back polymer layer placed on the back matching layer. An acoustic impedance of the acoustic absorption layer may be calculated based on mathematical formula 1.

The transparent ultrasound transducer may further comprise a front polymer layer placed on the front matching layer.

The front matching layer may comprise a composite material of ceramic and epoxy and the front polymer layer may comprise a pure polymer material.

The thickness of the piezoelectric unit may be half of a transmission wavelength λ, and the thickness of each of the front matching layer, the front polymer layer, and the back matching layer may be λ/4.
of the piezoelectric unit, the front matching layer, and the front polymer layer, and the back matching layer each may be approximately half the transmission wavelength λ.

The light transmission of the composite material constituting the front matching layer or the back matching layer may be determined by the volume fraction of ceramic particles, the size and shape of the ceramic particles, and the difference in the refractive index between ceramic and polymer.

The light transmission may provide a light transmittance of 80% or more at a thickness of ¼ wavelength at an acoustic impedance of 7 to 9 MRayl of the front matching layer or at an acoustic impedance of 3 to 6 MRayl of the back matching layer.

The acoustic impedance of the composite material constituting the front matching layer or the back matching layer may be determined by the bulk modulus and shear modulus, and density of the composite material.

The bulk modulus, shear modulus, and density of the composite material may be determined by the bulk modulus, shear modulus, and density of the polymer and ceramic particles, as well as the volume fraction of the ceramic particles in the composite material.

The average particle size of the ceramic particles, which is determined by the bulk modulus, shear modulus, and density of the composite material, may be controlled to be less than or equal to one-quarter of the wavelength.

The viscosity of the uncured mixture of the composite material may be determined by the average size, volume fraction, and shape of the ceramic particles. The viscosity of the uncured mixture of the composite material may be less than or equal to 10⁸ cPs.

Viscosity refers to the magnitude of resistance to flow in a fluid under a dynamic condition, specifically the resistance in the direction opposite to the flow or motion, and may refer to dynamic viscosity (η) or absolute viscosity. It may be expressed in units of centipoise (cP or cPs), which corresponds to 0.01 poise in the CGS unit system.

The transparency of the uncured mixture of the composite material may be determined by the average size, volume fraction, and shape of the ceramic particles, as well as the refractive index of the ceramic particles and the polymer. The transparency of the uncured mixture of the composite material may be 80% or higher.

The shape of the ceramic particles may include spherical, porous spherical, elliptical, plate-like, cylindrical, conical, or a combination thereof. Preferably, the shape of the ceramic particles is one that optimizes the viscosity and transparency of the composite material.

The transparent ultrasound transducer may further comprise a conductive ring member placed between the back matching layer and the back polymer layer.

The transparent ultrasound transducer may further comprise a case that accommodates a stacked structure of the front polymer layer, the front matching layer, the back matching layer, the back polymer layer, and the conductive ring member.

The piezoelectric unit may include a first transparent electrode formed on the front of the piezoelectric crystal and a second transparent electrode formed on the back of the piezoelectric crystal.

The transparent ultrasound transducer may further comprise a connecting electrode connecting the first transparent electrode and the case on one surface of the back polymer layer.

A method for fabricating a transparent ultrasound transducer, according to another aspect of the present disclosure for resolving the above-described technical problem, may comprise: applying a mixture in which a first particle is dispersed in a polymer material to one surface of a piezoelectric unit; degassing and curing the paste applied to one surface of the piezoelectric unit in a predetermined environment; and lapping and polishing the cured composite material to a design thickness to form a matching layer on one surface of the piezoelectric unit.

The first particle may include glass or a ceramic material which contains one or more materials selected from the silicate group, aluminum salt group, zirconium salt group, magnesium fluoride group, ytterbium salt composite, yttrium salt composite, and samarium salt composite. The polymer material may contain one or more materials selected from silicone, epoxy, urethane, polyethylene, polystyrene, and acrylic-based and sulfate-based polymerization resins.

The method for fabricating the transparent ultrasound transducer may further comprise forming a front polymer layer on a front matching layer when a matching layer placed on one surface of the piezoelectric unit is the front matching layer.

The method for fabricating the transparent transducer may further comprise forming another matching layer by applying a liquid or clay-like material on the other surface of the piezoelectric unit.

The method for fabricating the transparent ultrasound transducer may further comprise: when the additional matching layer is a back matching layer formed on the back of the piezoelectric unit, forming a back polymer layer on the back matching layer, disposing a conductive ring member connecting to a second transparent electrode of the piezoelectric unit between the piezoelectric unit and the back polymer layer; and placing a case that accommodates a stacked structure of the piezoelectric unit, the front matching layer, the back matching layer, the back polymer layer, and the conductive ring member.

The thickness of the piezoelectric unit may be half the transmission wavelength λ, and the thicknesses of the front matching layer, the front polymer layer, and the back matching layer may be λ/4 each.

### Advantageous Effects

According to the present disclosure, optical transparency may increase, and backward damping performance for the vibrations of a piezoelectric unit may improve by utilizing a transparent matching layer formed of a composite to ensure adherence to either side of the piezoelectric unit of a transparent ultrasound transducer.

In addition, according to the present disclosure, a new transparent ultrasound transducer having improved acoustic characteristics and being capable of exhibiting ultrasonic transceiving performance practically equivalent to that of a conventional opaque ultrasound transducer, and a method for fabricating the transducer may be provided.

In addition, according to the present disclosure, the issue of difficulty in maximizing acoustic wave transmission efficiency posed by substantially different acoustic transmission characteristics between the piezoelectric ceramic material used in fabricating an ultrasound transducer and human tissues (including water) may be addressed by utilizing a new transparent matching material exhibiting intermediate acoustic characteristics. In other words, a transparent ultrasound transducer utilizing a new transparent matching material to optimize acoustic characteristics and optical characteristics simultaneously, and a method for fabricating the transducer may be provided.

### DESCRIPTION OF DRAWINGS

FIG. 1 is a front view of a transparent ultrasound transducer (TUT) according to an embodiment of the present disclosure.

FIG. 2 is a schematic left-side view of a cross-section of a structure having a secondary front matching layer added to the TUT of FIG. 1 and cut along its vertical centerline.

FIG. 3 is an exploded perspective view of the TUT of FIG. 1 viewed from the left side.

FIG. 4 is a schematic view for describing the detailed configuration of a piezoelectric unit that may be adopted in TUT of FIG. 1.

FIG. 5 is an example view for describing a structure of the bonding surface between the piezoelectric unit and the matching layer that may be adopted in the TUT of FIG. 1.

FIG. 6 is an example view of the structure of the bonding surface between the piezoelectric unit and the matching layer of a comparison example.

FIG. 7 is a schematic view for describing a structure that may be adopted in the TUT in FIG. 1.

FIG. 8 is a schematic view showing the structure of the opaque ultrasound transducer in comparison example 1.

FIG. 9 is a schematic view showing the structure of the transparent ultrasound transducer in comparison example 2.

FIG. 10 is a flowchart for describing the main process in the fabricating method of the TUT according to an embodiment of the present disclosure.

FIG. 11 is a flowchart for describing an additional process that may be adopted in the TUT fabricating method in FIG. 10.

FIGS. 12 and 13 are graphs for describing conditions to be considered in the TUT fabricating method of the present embodiment.

FIG. 14 is a graph for describing the relationship between the acoustic impedance and viscosity of materials considered in the TUT fabricating method of the present embodiment.

FIG. 15 is a graph for describing the relationship between the acoustic impedance and light transmission considered in the TUT fabricating method of the present embodiment.

FIG. 16 is a graph showing the relationship between the acoustic impedance and the viscosity in various composites that may be adopted in the TUT of the present embodiment.

FIG. 17 is a graph showing the relationship between the acoustic impedance and the light transmission in various composites that may be adopted in the TUT of the present embodiment.

FIG. 18 is a partially enlarged view of the upper dotted portion of FIG. 17.

FIG. 19 shows graphs for describing the relationship between the volume fraction and longitudinal elastic velocity of each composite on each of the forward and backward sides considered in the TUT fabrication method of the present embodiment.

FIG. 20 is a graph for describing the relationship between the volume fraction and acoustic impedance of various composites on each of the forward and backward sides considered in the TUT fabricating method of the present embodiment.

FIG. 21 is a graph showing the light transmission as a function of the wavelength of the primary front matching layer fabricated by the TUT fabricating method of the present embodiment.

FIG. 22 is a diagram showing the light transmission of a composite that may be adopted in the front matching layer of the TUT of the present embodiment and a composite of a comparison example.

FIG. 23 is a graph showing the light transmission as a function of the wavelength of a back matching layer fabricated by the TUT fabricating method of the present embodiment.

FIG. 24 is a diagram for describing the light transmission of various composites that may be adopted in the back matching layer of the TUT of the present embodiment.

FIG. 25 is a graph for describing the effective acoustic impedance magnitude on the forward side of the present embodiment and comparison examples.

FIG. 26 is a graph for describing the phase angle of the effective acoustic impedance on the forward side of the present embodiment and comparison examples.

FIG. 27 is a graph for describing the effective impedance on the backward side of the present embodiment and comparison examples.

FIG. 28 is a graph showing a comparison between the performances of each TUT based on the measured forward effective acoustic impedance magnitudes in the present embodiment and comparison examples.

FIG. 29 is a graph showing a comparison between the performances of each TUT based on the measured forward effective impedance phases in the present embodiment and comparison examples.

FIG. 30 is a graph showing a comparison between light transmissions of a developed transparent element (embodiment) fabricated by the TUT fabricating method of the present embodiment and a conventional transparent element (comparison example).

FIG. 31 is a graph showing a comparison between the peak-to-peak voltages in the pulse-echo response waveform of the present embodiment and comparison examples.

FIG. 32 is a graph showing a comparison between full-width-at-half-maximum (FWHW) in the pulse-echo response waveform of the present embodiment and comparison examples.

FIG. 33 is a graph showing echo frequency analysis results of the present embodiment and comparison examples.

### MODE FOR INVENTION

Since the present disclosure may be modified in various ways and implemented in various forms, specific exemplary embodiments are illustrated in the accompanying drawings and described in detail in the following detailed description. However, it should be understood that the present disclosure is not intended to limit to the specific embodiments, but includes all modifications, equivalents, and substitutions that fall within the scope of the disclosure.

Relational terms such as first, second, and the like may be used for describing various elements, but the elements should not be limited by the terms. These terms are only used to distinguish one element from another. For example, a first component may be named a second component without departing from the scope of the present disclosure, and the second component may also be similarly named the first component. The term “and/or” means any one or a combination of a plurality of related and described items.

In exemplary embodiments of the present disclosure, “at least one of A and B” may refer to “at least one of A or B” or “at least one of combinations of one or more of A and B”. In addition, “one or more of A and B” may refer to “one or more of A or B” or “one or more of combinations of one or more of A and B”.

When it is mentioned that a certain component is “coupled with” or “connected with” another component, it should be understood that the certain component is directly “coupled with” or “connected with” to the other component or a further component may be disposed therebetween. In contrast, when it is mentioned that a certain component is “directly coupled with” or “directly connected with” another component, it will be understood that a further component is not disposed therebetween.

The terms used in the present disclosure are only used to describe specific exemplary embodiments, and are not intended to limit the present disclosure. The singular expression includes the plural expression unless the context clearly dictates otherwise. In the present disclosure, terms such as ‘comprise’ or ‘have’ are intended to designate that a feature, number, step, operation, component, part, or combination thereof described in the specification exists, but it should be understood that the terms do not preclude existence or addition of one or more features, numbers, steps, operations, components, parts, or combinations thereof.

Unless otherwise defined, all terms (including technical and scientific terms) used herein have the same meaning as commonly understood by one of ordinary skill in the art to which this disclosure belongs. Terms that are generally used and have been in dictionaries should be construed as having meanings matched with contextual meanings in the art. In this description, unless defined clearly, terms are not necessarily construed as having formal meanings.

Hereinafter, forms of the present disclosure will be described in detail with reference to the accompanying drawings. In describing the disclosure, to facilitate the entire understanding of the disclosure, like numbers refer to like elements throughout the description of the figures and the repetitive description thereof will be omitted.

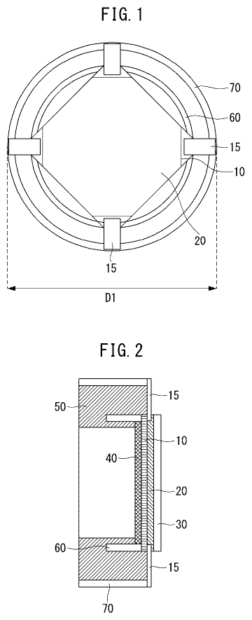

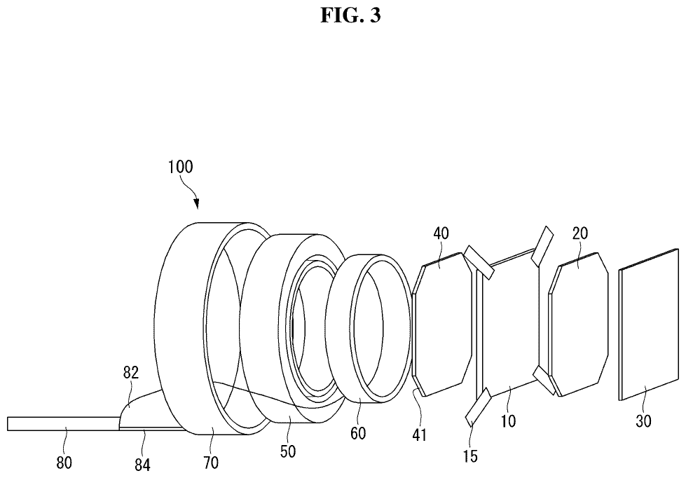

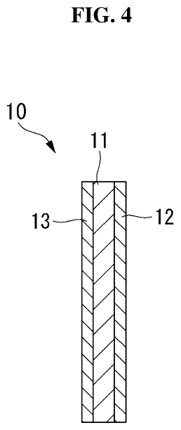

FIG. 1 is a front view of a transparent ultrasound transducer (TUT) according to an embodiment of the present disclosure. FIG. 2 is a schematic left-side view of a cross-section of a structure having a secondary front matching layer added to the TUT of FIG. 1 and cut along its vertical centerline. FIG. 3 is an exploded perspective view of the TUT of FIG. 1 viewed from the left side. Further, FIG. 4 is a schematic view for describing the detailed configuration of a piezoelectric unit that may be adopted in TUT of FIG. 1.

FIGS. 1 to 4 show that a transparent ultrasonic transducer (TUT) 100 is a single resonance device having high sensitivity and high bandwidth characteristics and may include a piezoelectric unit 10, front matching layers 20, 30, and back acoustic absorption layers 40, 50. The back acoustic absorption layers may be simply referred to as acoustic absorption layers.

The TUT 100 may have an approximately flat cylindrical shape, include a center portion in a transparent form to ensure visibility of the back through the front, and have a diameter D1 of approximately 10 mm to 20 mm in size when viewed from the front.

The TUT 100 may include matching layers 20 and/or 40 formed on at least one of the front and the back of the piezoelectric unit 10 without a bonding gap and formed of transparent matching and acoustic absorption materials having appropriate acoustic impedances. The acoustic impedance may be determined by the speed of the acoustic wave and the density of the material.

Specifically, the TUT 100 may include a secondary front matching layer 30 on a primary front matching layer 20. The primary front matching layer 20 may be referred to as a first front matching layer or simply a front matching layer, and the secondary front matching layer 30 may be referred to as a second front matching layer or a front polymer layer.

The back acoustic absorption layer may include a back matching layer 40 forming a back side boundary of the piezoelectric unit 10 and absorbing the acoustic impedance traveling towards the back of the piezoelectric unit 10. In addition, the back acoustic absorption layer may further include a back polymer layer 50 placed on the back matching layer 40.

In addition, as shown in FIGS. 2 and 4, the TUT 100 may further include a conductive ring member 60. The conductive ring member 60 may be simply referred to as a conductive ring. The conductive ring 60 may be supported by the back polymer layer 50 to ensure tight adherence to a second transparent electrode 13 placed on the other surface of a thin film-shaped piezoelectric element 11 of the piezoelectric unit 10. The thickness of the thin film-shaped piezoelectric element 11 may be a few micrometers to several thousand micrometers.

As shown in FIG. 4, the piezoelectric unit 10 may have a structure having the piezoelectric element 11, a first transparent electrode 12 coated to the front of the piezoelectric element 11, and a second transparent electrode 13 coated to the back of the piezoelectric element 11.

In addition, FIGS. 2 and 3 show that the TUT 100 may further include a case 70 accommodating a stacked structure of the piezoelectric unit 10, primary front matching layer 20, back acoustic absorption layers 40, 50, and conductive ring 60.

The case 70 may have a conductive tube shape such as a brass tube. The case 70 may be electrically disconnected from the conductive ring 60 by the back polymer layer 50. Further, one end of the case 70 may be coupled to connecting electrodes 15 contacting the first transparent electrode 12 placed on one surface of the piezoelectric element 11 of the piezoelectric unit 10. To this end, the back matching layer 40 may include side edges 41 formed by cutting corners to expose the first transparent electrode 12.

In addition, as shown in FIG. 3, the TUT 100 may be coupled to a cable 80 connecting a ground wire 84 to the case 70. The cable 80 may include a coaxial cable having a predetermined diameter and structure. A signal wire 82 of the cable 80 may be connected to the conductive ring 60. The cable 80 may be coupled in a structure having a predetermined connector when connected to the TUT 100.

The TUT 100 described above is shown to have a structure in which the transducer is accommodated in the cylindrical case 70, but the present disclosure is not limited to such a configuration. When viewed from the front as in FIG. 1, the TUT 100 may include approximately triangular, rectangular, or polygonal shapes or a shape with at least one edge or corner in a portion and at least one arc in the remaining portion, in addition to an approximate circular or elliptical shape.

To be more specific about each component of the TUT 100 described above, the piezoelectric unit 10 may have a thin-film structure that generates vibrations in response to an electrical signal or generates electrical signals in response to a vibration. The piezoelectric unit 10 may generate vibrations and reflect acoustic waves at the front and back boundaries to amplify the intensity of the acoustic waves within. The wavelength of the amplified acoustic waves may be determined by the thickness of the piezoelectric unit 10 or piezoelectric element 11.

The front matching layer 20 may be formed on one surface or the front of the piezoelectric unit 100 utilizing a composite freely molded into a liquid or clay-like mixture form. The material of the front matching layer 20 may be a composite made of ceramic and epoxy. In the forming process of the front matching layer 20, the front matching layer 20 in a tightly attached state to one surface of the piezoelectric unit 10 may be formed using the method for applying or attaching the composite onto the front of the piezoelectric unit 10 and then curing and cutting it to the target thickness.

The acoustic impedance of the front matching layer 20 may be 7 to 9 MRayl. Further, the front matching layer 20 may be formed to have a light transmission allowing light transmittance of 80% or more at a thickness of ½ transmission wavelength in a state where the acoustic impedance of the mixture or composite is designed to be 7 to 9 MRayl before the front matching layer 20 is cured.

The front polymer layer 30 may be made of a polymer material. The refractive index of the front polymer layer 30 may be the same as or similar to the refractive index of the front matching layer 20. For example, the front polymer layer may be formed to have a refractive index similar to that of the front matching layer formed of epoxy or urethane material. The front polymer layer 30 may be formed on the front matching layer 20 and have a smooth surface while the thickness is adjusted using a method such as spin coating or spray coating. In another embodiment, the front polymer layer 30 may be formed to have a smooth surface using a method for forming, curing, and then polishing a thick layer.

The back matching layer 40 may be formed by applying a back matching material which is a composite to the back of the piezoelectric unit. The back matching material may be the same as the material of the front matching layer 20.

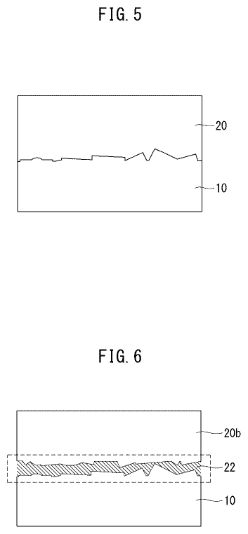

FIG. 5 is an example view for describing a structure of the bonding surface between the piezoelectric unit and the matching layer that may be adopted in the TUT of FIG. 1. FIG. 6 is an example view of the structure of the bonding surface between the piezoelectric unit and the matching layer of a comparison example.

FIG. 5 shows that the front matching layer 20 of the present embodiment may be directly formed by the method for preparing a liquid composite or a composite of a clayey material first and then applying or coating the ingredient to the front of the piezoelectric unit 10 to the target thickness. In addition, the front matching layer 20 may be formed to have a target thickness through a cutting process after the front matching layer is formed to a thickness greater than the target thickness.

The front matching layer 20 may be formed without using a separate adhesive on the front of the piezoelectric unit 10 having a smooth surface through cutting, and the gap between the formed front matching layer 20 and the piezoelectric unit 10 may be practically eliminated.

On the other hand, as shown in the enlarged view in FIG. 6, the two surfaces of the separately cut piezoelectric material and matching layer are bonded using an adhesive 22, so the ultrasound transducer of the comparison example may have a gap in the bonding area and may have an issue of serious poor performance.

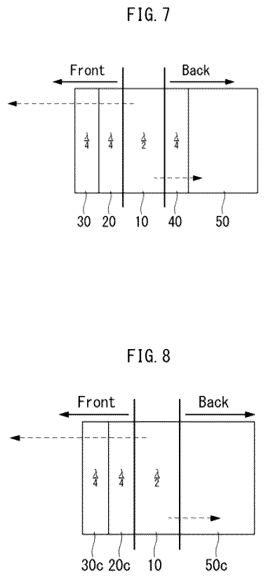

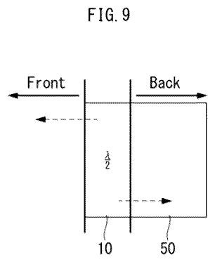

FIG. 7 is a schematic view for describing a structure that may be adopted in the TUT in FIG. 1. FIG. 8 is a schematic view showing the structure of the opaque ultrasound transducer in comparison example 1. Further, FIG. 9 is a schematic view showing the structure of the transparent ultrasound transducer in comparison example FIG. 7 shows that the front matching layer 20 and the back matching layer 40 installed on either surface of the piezoelectric unit 10 of the TUT are formed utilizing a composite that may be easily molded into a liquid or clay-like mixture form while having an acoustic impedance of 7 to 9 MRayl. The matching layers 20, 40 may be matching layers having the same mechanical structure and performance as a conventional opaque ultrasound transducer except for transparency.

In addition, dual layers consisting of the back matching layer 40 made of a transparent composite and the back polymer layer 50 made of a polymer material are formed in the back acoustic absorption layer in the TUT of the present embodiment so that a transparent structure that may sufficiently absorb acoustic waves while adjusting the response time of the transducer to an appropriate range may be provided.

The effective acoustic impedance of the back acoustic absorption layer may be calculated using the following mathematical formula 1.

$${Z}_{eff} = {Z}_{1} \frac{{Z}_{B} + {iZ}_{1} tan ( \frac{2 π}{λ} l )}{{Z}_{1} + {iZ}_{B} tan ( \frac{2 π}{λ} l )} \qquad [ Mathematical Formula 1 ]$$

In the mathematical formula 1, Z_{eff} is the effective acoustic impedance, Z₁ is the acoustic impedance of the back matching layer, Z_{B} is the acoustic impedance of the back polymer layer, l is the length of the back matching layer, and λ is the wavelength.

In the TUT of the present embodiment, the thickness of the transparent piezoelectric unit 10, the thickness of the transparent front matching layer 20, the thickness of the front polymer layer 30, and the thickness of the back matching layer may be ½ the transmission wavelength λ each. The thickness of each of these units may be adjusted near ¼ wavelength or ½ wavelength. Based on the transmission wavelength λ, the thickness of the piezoelectric unit 10 may be ½, the thickness of the transparent front matching layer 20 may be ¼, the thickness of the transparent front polymer layer 30 may be ¼, and the thickness of the transparent back matching layer 40 may be ¼, depending on the implementation.

Acoustic waves are emitted to the front of the TUT, and the acoustic waves traveling towards the back of the TUT are absorbed by the back acoustic absorbing layer 40, 50.

On the other hand, as shown in FIG. 8, the opaque ultrasound transducer of the comparison example 1 includes a matching layer 20c formed of an opaque composite on the front of a transparent piezoelectric unit 10 and a transparent polymer layer 30c attached onto the top of the matching layer 20c and includes a structure consisting of an opaque polymer layer 50c on the back of the piezoelectric unit 10.

In addition, as shown in FIG. 9, the transparent ultrasound transducer of the comparison example 2 has a structure consisting of a transparent piezoelectric unit 10 and a transparent polymer layer 50 attached to the back of the piezoelectric unit 10.

According to the present embodiment described above, the conventional issues on matching and acoustic absorption materials for a transparent ultrasound transducer may be effectively resolved. In other words, conventional materials with an acoustic impedance of 30 MRayl or higher, such as metal materials and polycrystalline ceramic materials, are inherently opaque. Even when transparent, they have a high refractive index of 1.6 or higher, resulting in significant internal scattering and thus a very low overall light transmission when composites are formed with polymer materials.

In particular, the matching layer composite used in the TUT of the present embodiment may be easily molded into a liquid or clay-like mixture form while having an acoustic impedance of 7 to 9 MRayl, so the issue of the related art described above may be resolved.

On the other hand, the embodiment described above shows the case where the thickness of ½ wavelength and the thickness of ¼ wavelength are selectively used, but the present disclosure is not limited to such a configuration, and the optimal thickness of each component may be selected near approximately ½ wavelength and ¼ wavelength, or the optimal thickness of all components may be selected near approximately ½ wavelength.

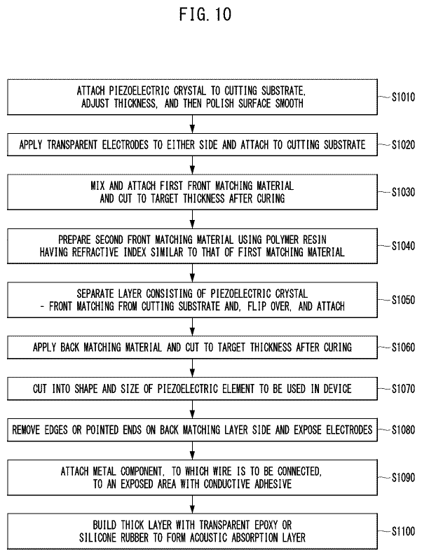

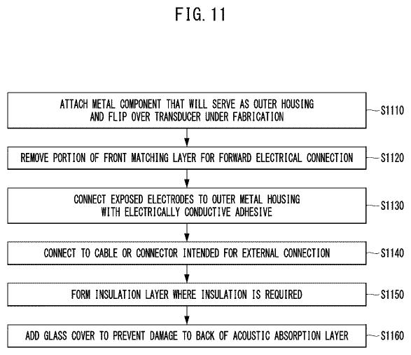

FIG. 10 is a flowchart for describing the main process in the fabricating method of the TUT according to an embodiment of the present disclosure.

FIG. 10 shows that the TUT fabricating method involves first attaching a piezoelectric crystal to a cutting substrate, adjusting the thickness of the attached piezoelectric crystal, and then polishing its surface smooth (S1010). The piezoelectric crystal may be simply referred to as a piezoelectric element.

Next, a transparent electrode such as indium tin oxide (ITO) is applied to either side of the piezoelectric crystal and then attached to the cutting substrate (S1020).

Next, a first front matching material is mixed and attached by an applying method and the attached first front matching material is cut to the target thickness after curing (S1030). The first front matching material is for forming a transparent first front matching layer and may contain at least one of epoxy and urethane.

Next, a second front matching is prepared utilizing a polymer material having a refractive index similar to that of the first front matching material (S1040). The polymer material may contain transparent polymer or resin. The second matching material is for forming a front polymer layer or a second front matching layer.

Next, a smooth surface may be made by adjusting the thickness of the second front matching material applied onto the first front matching layer using a method such as spin coating or spray coating, or a smooth surface may be made through a method for polishing the thick layer after curing and cutting.

On the other hand, depending on the modified implementation, the second front matching layer may have a concave or convex lens-shaped outer surface to allow for an acoustic lens function.

Next, the stacked structure consisting of a piezoelectric crystal-front matching structure is separated from the cutting substrate and flipped over to be attached (S1050).

Next, the back matching material is applied to the back of the piezoelectric crystal and then cut to the target thickness after curing (S1060). The back matching material may be practically the same as the first front matching material but is not limited thereto. The back matching material may additionally contain a material having an advantage in acoustic absorption performance.

Next, the back matching-piezoelectric crystal-front matching structure is cut into the shape and size of the piezoelectric element to be used in an ultrasound transducer device (S1070).

Next, portions such as edges or pointed ends on the back matching layer side are removed to expose electrodes (S1080).

Next, a metal component, to which a wire is to be connected, is attached to the exposed area with a conductive adhesive (S1090).

Then, a thick layer is built utilizing transparent epoxy, urethane, or silicone rubber to complete the back acoustic absorption layer (S1100).

According to the configuration described above, the ultrasound transducer of the present embodiment may include a multi-layered front matching layer installed on the front of a piezoelectric unit that includes piezoelectric crystal and a back matching layer installed on the back of the piezoelectric unit. Here, the front matching layer may include a relatively thin first front matching layer formed by applying a front matching material which is a composite and a relatively thick second front matching layer formed utilizing a polymer material with a refractive index similar to that of the first front matching layer. Further, the back matching layer may include a relatively thin transparent back thin-film layer formed by applying a back matching material which is a composite and a transparent back thick-film layer which is very thick compared to the thin-film layer.

On the other hand, the present embodiment has been described focusing on a configuration in which edge portions or pointed ends on the back matching layer side are removed to expose electrodes, but the present disclosure is not limited to such a configuration and a configuration in which electrodes are exposed through a fabricating process of not forming a matching layer in the corresponding areas instead of removing a matching layer may be included.

FIG. 11 is a flowchart for describing an additional process that may be adopted in the TUT fabricating method in FIG. 10.

FIG. 11 shows that the TUT fabricating method may involve attaching a metal component that will serve as an outer housing of the previously prepared back matching-piezoelectric crystal-front matching structure to the back of the structure (S1110). The housing may be made of a metal material. Further, a transducer under fabrication, with the housing attached, may be flipped over for its back side to face the bottom of the workbench.

Next, a portion of the edge of the front matching layer that will face forward may be removed for the electrical connection on the front side, that is the forward side (S1120).

Next, the exposed electrodes may be electrically connected to the metal housing placed on the outer side using an electrically conductive adhesive (S1130). The exposed electrode may be a transparent electrode coated to the front of the piezoelectric unit.

Next, the metal housing may be connected to a cable or connector intended for external connection (S1140). The metal housing may be connected to the ground wire of the cable or connector.

Next, an insulation film may be formed in the area where insulation is required (S1150). The area where the insulation is required may be an area with an exposed electrode or an area connecting to the cable or connector.

Next, a glass cover may be additionally placed to prevent damage such as a scratch on the back of the back acoustic absorption layer (S1160). The glass cover may also be referred to as a contact coupling.

On the other hand, the present embodiment has been described focusing on a configuration where the forward side, that is, a portion of an edge of the front matching layer placed to face forward for electrical connection of the front side, is removed, but the present disclosure is not limited to such a configuration, and a process allowing exposition of the electrodes without removing the corresponding matching layer may be included.

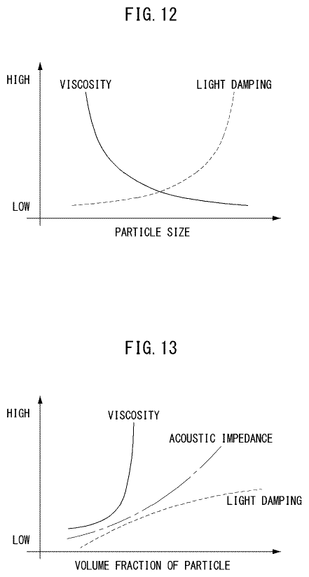

FIGS. 12 and 13 are graphs for describing conditions to be considered in the TUT fabricating method of the present embodiment.

FIGS. 12 and 13 show that all work is performed at 100 °C or below to prevent damage to the piezoelectric crystal. In other words, it is not easy to use high-temperature molding materials in TUT fabrication.

In addition, when a transparent ceramic material, which is not much different from a general polymer material with a refractive index of 1.45 to 1.55, is used, the acoustic impedance of the particle itself is as low as 10 to 15 MRayl, so the ceramic ratio must be set very high to achieve the acoustic impedance of the composite as high as 7 to 9 MRayl.

In addition, to resolve the bonding gap issue between the piezoelectric unit and the matching layer, a method for dispersing a powder material into a liquid or clay-like polymer material and curing the polymer material is used. However, when this method is used, the viscosity tends to shoot up exponentially when raising the volume fraction of the particle, so it is not easy to properly increase the volume fraction.

Therefore, the transparent composite for the TUT of the present embodiment is prepared such that the light transmission, acoustic impedance, and viscosity of the mixture before the composite is cured are all in the appropriate ranges.

In other words, the light transmission may be determined based on the volume fraction of ceramic the particle, the size and shape of the particle, and the difference in the refractive index between polymers and ceramics.

Here, the light transmission is set to ensure light transmission at an acoustic impedance of 7 to 9 MRayl for the front matching layer and at about 3 to 6 MRayl for the back matching layer at a thickness of ½ wavelength. Here, transparency or light transmission means having a transmittance of 80% or more.

In other words, the light transmission of a composite constituting the front matching layer or back matching layer may be determined by the volume fraction of ceramic particle, the average size of the ceramic particle, the volume fraction of the ceramic particle, the shape of the ceramic particle, the refractive index of the ceramic particle, and the refractive index of the polymer. The light transmission may be set to a light transmittance of 80% or more at a thickness of ¼ wavelength or at a thickness of ½ wavelength, preferably at ¼ wavelength, at the acoustic impedance of 7 to 9 MRayl for the front matching layer or at the acoustic impedance of 3 to 6 MRayl for the back matching layer. The light transmission of the mixture before the composite is cured may be 80% or more.

The acoustic impedance may be determined based on the volume fraction of the ceramic particle and the bulk modulus and shear modulus of ceramic and polymer. In other words, the acoustic impedance of the front matching layer or the back matching layer may be determined by the bulk and shear moduli, and density of the composite. The bulk and shear moduli and density of the composite may be determined by the bulk and shear moduli and density of the polymer and ceramic particle and the volume fraction of the ceramic particle in the composite. Further, the average size of the ceramic particle, determined by the bulk and shear moduli and density of the composite, may be adjusted to ¼ wavelength or less.

The acoustic impedance Z determined by the bulk and shear moduli and density of the composite described above may be expressed mathematically by the following mathematical formula 2.

$$Z = \sqrt{( K + \frac{4}{3} G ) ( ( 1 - V ) {ρ}_{matrix} + V {ρ}_{filler} )} \qquad [ Mathematical Formula 2 ]$$

In the mathematical formula 2, Z is the acoustic impedance of the composite, K is the bulk modulus of the composite, G is the shear modulus of the composite, V is the volume fraction of the ceramic particle, ρₘₐₜᵣᵢₓ is the density of the polymer, ρ_{filler} is the density of the ceramic particle, and ((1−V)ρₘₐₜᵣᵢₓ+Vρ_{filler}) is the density of the composite.

Further, the viscosity of the mixture before curing may be determined based on the volume fraction of the ceramic particle and the size and shape of the particle. In other words, the viscosity of the mixture before the composite is cured may be determined by the average size of the ceramic particle, the volume fraction of the ceramic particle, and the shape of the ceramic particle. The viscosity of the mixture before the composite is cured may be 10⁸ cPs or less. In addition, the viscosity of the mixture before curing may be set to remain in the mixable range, at an acoustic impedance of 7 to 9 MRayl, and at about 3 to 6 MRayl, give or take, in the case of the back matching layer.

In addition, in the present embodiment, the acoustic impedance of the composite depending on the elasticity characteristics of each particle may be expressed by a function of the volume fraction and the composition of the composite may be determined using it.

The bulk modulus K of the composite may be expressed by the following mathematical formula 3.

$$K = {K}_{matrix} + V \frac{( 3 K + 4 G ) ( {K}_{filler} - {K}_{matrix} )}{3 K + 4 G + 3 ( {K}_{filler} - {K}_{matrix} )} \qquad [ Mathematical formula 3 ]$$

The shear modulus G of the composite may be expressed by the following mathematical formula 4.

$$G = {G}_{matrix} + V \frac{5 ( 3 K + 4 G ) G ( {G}_{filler} - {G}_{matrix} )}{( 15 K + 20 G ) G + 6 ( K + 2 G ) ( {G}_{filler} - {G}_{matrix} )} \qquad [ Mathematical formula 4 ]$$

In the mathematical formulae 3 and 4, K is the bulk modulus of the composite, G is the shear modulus of the composite, V is the volume fraction of the ceramic particle, matrix is the property indication, and filler is the proper indication of the ceramic particle.

The shape of the ceramic particle described above may include spherical, porous spherical, elliptical, plate-like, cylindrical, or conical shapes or a combination thereof. Preferably, the shape of the ceramic particle is one that may optimize the viscosity and light transmission of the composite.

The longitudinal velocity C_{L} of the composite for calculating the average size of the ceramic particle determined by the bulk modulus and shear modulus of the composite and the density of the composite may be expressed by the following mathematical formula 5.

$${C}_{L} = \sqrt{\frac{K + \frac{4}{3} G}{ρ}} \qquad [ Mathematical formula 5 ]$$

In the mathematical formula 5, K is the bulk modulus of the composite, G is the shear modulus of the composite, and p is the density of the composite respectively.

The average size of the ceramic particle may be defined using the longitudinal velocity of the composite. In other words, when the thickness of the matching layer is ¼ wavelength, the average size SA of the ceramic particle may be expressed by the following mathematical formula 6.

$${S}_{A} = {C}_{L} \times ( \frac{1}{4} \times P ) \qquad [ Mathematical formula 6 ]$$

In the mathematical formula 6, C_{L} is the longitudinal velocity of the composite, ¼ is the thickness of the matching layer, and P is the period with respect to the transmission wavelength.

The average size of the ceramic particles constituting the matching layer cannot be greater than the matching layer thickness and is preferably adjusted to ⅕ to 1/10 or less of the matching layer thickness for uniform transmission of the acoustic wave.

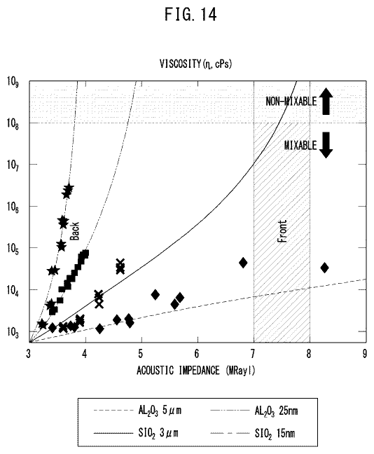

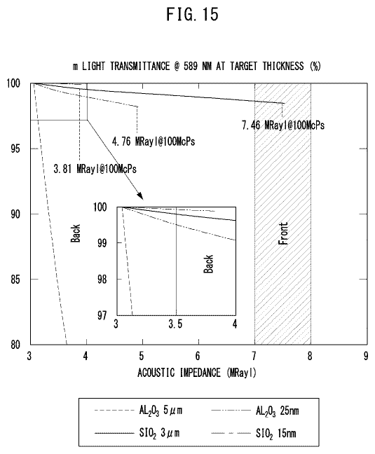

The results of experiments performed utilizing aluminum oxide (Al₂O₃) with a particle size of 5 μm, aluminum oxide (Al₂O₃) with a particle size of 25 nm, silicon dioxide (SiO₂) with a particle size of 3 μm, and silicon dioxide (SiO₂) with a particle size of 15 nm as composites are shown in FIGS. 14 and 15.

FIG. 14 is a graph for describing the relationship between the acoustic impedance and viscosity of materials considered in the TUT fabricating method of the present embodiment.

As shown in FIG. 14, changes in viscosity as a function of the changes in the volume fraction of each particle may be measured, and based on this, the viscosity and limit mixing ratio as a function of the acoustic impedance may be estimated. The viscosity includes absolute viscosity or dynamic viscosity. However, based on the viscosity analysis, the viscosities or mixing ratios falling in non-usable regions, where mixing is impossible, at the target acoustic impedance is excluded.

As a result of the experiment, aluminum oxide (Al₂O₃) with a particle size of 5 μm was measured to have an acoustic impedance of about 3 to about 9.2 MRayl at a viscosity of about 10³ to 10⁸ (r, cPs). Aluminum oxide (Al₂O₃) with a particle size of 25 nm was measured to have an acoustic impedance of about 3 to about 4.9 MRayl at a viscosity of 103 to 108 (r, cPs). Silicon dioxide (SiO₂) with a particle size of 3 μm was measured to have an acoustic impedance of 3 to 7.5 MRayl at a viscosity of about 10³ to 10⁸ (r, cPs). Further, Silicon dioxide (SiO₂) with a particle size of 15 nm was measured to have an acoustic impedance of about 3 to about 3.9 MRayl at a viscosity of about 10³ to 10⁸ (r, cPs). Here, viscosities of 10⁸ (r, cPs) or above are considered unmixable and thus excluded from consideration in the selection of viscosity or mixing ratio.

According to the above experimental results, it is found that aluminum oxide Al₂O₃ with a particle size of 5 μm may be used in a composite mixed at a volume fraction with a viscosity of about 10³ to 10⁴ (r, cPs) to obtain an acoustic impedance of 7 to 8 MRayl suitable for the front matching layer. In addition, it is found that silicon dioxide SiO₂ with a particle size of 3 μm may be used in a composite mixed at a volume fraction with a viscosity of about 10⁷ to 10⁸ (r, cPs).

FIG. 15 is a graph for describing the relationship between the acoustic impedance and light transmission considered in the TUT fabricating method of the present embodiment.

As shown in FIG. 15, the scattering coefficient as a function of the acoustic impedance changes may be estimated based on the theory of light scattering as a function of the volume fraction.

Based on the results of experiments and simulations, the combination of polymer and ceramic that simultaneously ensures light transmission and acoustic impedance after proper curing and viscosity before curing may be determined.

For example, in the case of a back matching layer in the range of 3 to 6 MRayl, all types of ceramic particles were found capable of adequately satisfying the acoustic impedance and viscosity conditions. However, considering the light transmission, at least one material selected from the first silicon dioxide composite, the second silicon dioxide composite, the ytterbium fluoride (YbF₃) composite, the yttrium fluoride (YF₃) composite, and samarium fluoride (SmF₃) is suitable for a back matching layer. For example, ytterbium salts may be one or more of YbCl₃, YbF₃, Ybl₂, Yb(NO₃)₃, Yb(CH₃CO₂)₃, and Yb(C₉H₂₁O₃) and samarium salts may be one or more of SmI₂, SmI₃, SmCl₃, Sm(NO₃)₃, Sm(CH₃CO₂)₃, SmPO₄, Sm(C₉H₂₁O₃), Sm₂(SO₄)₃, and Sm(C₅H₇O₂)₃.

For another example, when a front matching layer is fabricated in a range of 7 to 9 MRayl, at least one material selected from the first silicon dioxide composite, the ytterbium fluoride composite, the yttrium fluoride composite, and the samarium fluoride composite was found suitable for the type of ceramic particle that simultaneously satisfies the acoustic impedance, light transmission, and viscosity.

For still another example, the acoustic impedances of aluminum oxide (Al₂O₃) with a particle size of 5 μm (‘the first aluminum oxide composite’ hereinafter), aluminum oxide (Al₂O₃) with a particle size of 25 nm (‘the second aluminum oxide composite’ hereinafter), silicon dioxide (SiO₂) with a particle size of 3 μm (‘the first silicon dioxide composite’ hereinafter), and silicon dioxide (SiO₂) with a particle size of 15 nm (‘the second silicon dioxide composite’ hereinafter) were measured to be 3.65 MRayl, 4.76 MRayl, 7.46 MRayl, and 3.81 MRayl respectively in the order of description.

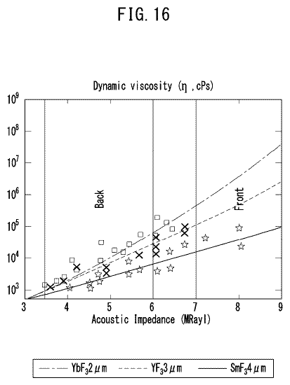

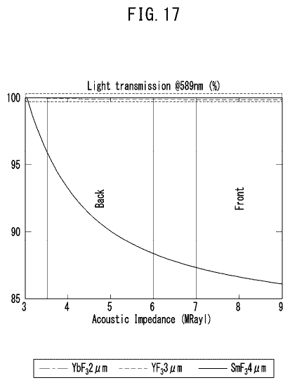

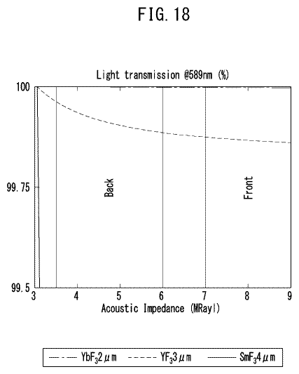

FIG. 16 is a graph showing the relationship between the acoustic impedance and the viscosity in various composites that may be adopted in the TUT of the present embodiment. FIG. 17 is a graph showing the relationship between the acoustic impedance and the light transmission in various composites that may be adopted in the TUT of the present embodiment. FIG. 18 is a partially enlarged view of the upper dotted portion of FIG. 17.

FIGS. 16 to 18 show that as a result of the experiments on the dynamic viscosity, acoustic impedance, and light transmission of various composites, the ytterbium fluoride (YbF₃) composite, the yttrium fluoride (YF₃) composite, and samarium fluoride (SmF₃) in addition to the first silicon dioxide composite and the second silicon dioxide composite are found suitable for the back matching layer and front matching layer among the conventional ceramic particle.

As shown in FIG. 16, the ytterbium fluoride (YbF₃) composite exhibited an acoustic impedance of about 3 to 9 MRayl at viscosity conditions of about 10³ to 10⁸, the yttrium fluoride (YF₃) composite exhibited an acoustic impedance of about 3 to 9 MRayl at viscosity conditions of about 10³ to 10⁷, and the samarium fluoride (SmF₃) composite exhibited an acoustic impedance of about 3 to 9 MRayl at viscosity conditions of about 10³ to 10⁵.

As shown in FIG. 17, it is found that, for the light with a wavelength of 589 nm, the ytterbium fluoride (YbF₃) composite has a light transmission of almost 100%, the yttrium fluoride (YF₃) composite has a light transmission of almost 100%, and the samarium fluoride (SmF₃) composite has a light transmission of about 100 to 85% at acoustic impedance conditions of about 3 to 9 MRayl.

In particular, as shown in FIG. 18, it is found that the ytterbium fluoride (YbF₃) composite has a light transmission of practically 100% for a light with a wavelength of 589 nm at acoustic impedance conditions of 3 to 9 MRayl and the yttrium fluoride (YF₃) composite has a light transmission of about 100 to 99.85% for a light with a wavelength of 589 nm at acoustic impedance conditions of about 3 to 9 MRayl.

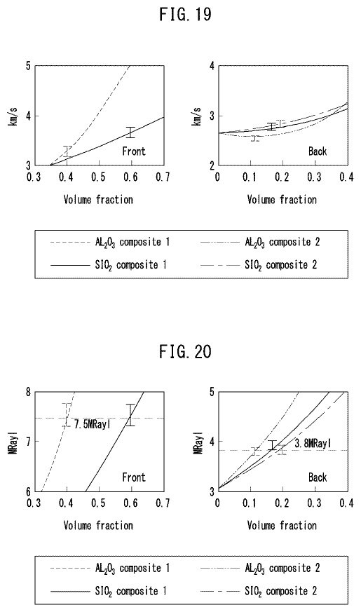

FIG. 19 shows graphs for describing the relationship between the volume fraction and longitudinal elastic velocity of each composite on each of the forward and backward sides considered in the TUT fabrication method of the present embodiment.

FIG. 19 shows the results of the experiments on the longitudinal acoustic velocity as a function of the volume fraction of a transparent matching layer material of the TUT of the present embodiment.

In other words, when the volume fraction of the first aluminum oxide composite (Al₂O₃ composite 1) used in the front matching layer of the TUT is increased from 0.3 up to 0.7, the acoustic velocity proportionally increases from about 3 km/s at a volume fraction of about 0.35 up to about 5 km/s at a volume fraction of about 0.6.

In addition, when the volume fraction of the second aluminum oxide composite (Al₂O₃ composite 2) used in the back matching layer of the TUT is increased from 0 up to 0.4, the acoustic velocity changes to about 2.6 km/s, about 2.5 km/s, about 2.8 km/s, and about 3.3 km/s respectively at volume fractions of 0, 0.1, 0.2, 0.3, and 0.4 in the order of description.

In addition, when the volume fraction of the first silicon dioxide composite (SiO₂ composite 1) used in the front and back matching layer of the TUT is increased from 0 up to 0.7, the acoustic velocity gradually increases in proportion from about 2.6 km/s at a volume fraction of 0 up to about 4 km/s at a volume fraction of 0.7.

In addition, when the volume fraction of the second silicon dioxide composite (SiO₂ composite 2) used in the back matching layer of the TUT is increased from 0 up to 0.4, the acoustic velocity gradually increases in proportion from about 2.6 km/s at a volume fraction of 0 up to about 3.2 km/s at a volume fraction of 0.4.

FIG. 20 is a graph for describing the relationship between the volume fraction and acoustic impedance of various composites on each of the forward and backward sides considered in the TUT fabricating method of the present embodiment.

FIG. 20 shows the results of the experiments on the acoustic impedance as a function of the volume fraction of transparent matching layer materials of the TUT of the present embodiment.

In other words, when the volume fraction of the first aluminum oxide composite (Al₂O₃ composite 1) used in the front matching layer of the TUT is increased from 0.3 up to 0.7, the acoustic impedance gradually increases in proportion from about 6 MRayl at a volume fraction of about 0.32 up to about 8 MRayl at a volume fraction of about 0.45 as the volume fraction increases.

In addition, when the volume fraction of the second aluminum oxide composite (Al₂O₃ composite 2) used in the back matching layer of the TUT is increased from 0 up to 0.4, the acoustic impedance gradually increases in proportion from about 3 MRayl at a volume fraction of 0 up to about 5 MRayl at a volume fraction of about 0.25 as the volume fraction increases.

In addition, when the volume fraction of the first silicon dioxide composite (SiO₂ composite 1) used in the front and back matching layers of the TUT is increased from 0 up to 0.7, the acoustic impedance gradually increases in proportion from about 3 MRayl at a volume fraction of 0 up to about 8 MRayl at a volume fraction of about 0.65 as the volume fraction increases.

In addition, when the volume fraction of the second silicon dioxide composite (SiO₂ composite 2) used in the back matching layer of the TUT is increased from 0 up to 0.4, the acoustic impedance gradually increases in proportion from about 3 MRayl at a volume fraction of 0 up to about 5 MRayl at a volume fraction of about 0.4.

In this way, the volume fraction satisfying the acoustic impedance required for each of the front matching layer and back matching layer of the TUT, such as 7.5 MRayl and 3.8 MRayl for example, is found for each composite.

A brief description of how to prepare a mixture of composites based on the experimental results described above is as follows. In other words, stability at room temperature may be increased by sufficiently degassing and cooling both the epoxy resin and hardener in a vacuum during preparatory work. When the target viscosity is low, the powder to be added is mixed only into the epoxy resin and is stirred well until a uniform liquid state is approached, and the mixture is degassed in a vacuum. Then, the hardener is mixed thereinto and the mixture is applied to an application area of the piezoelectric crystal and then may be degassed again in a vacuum.

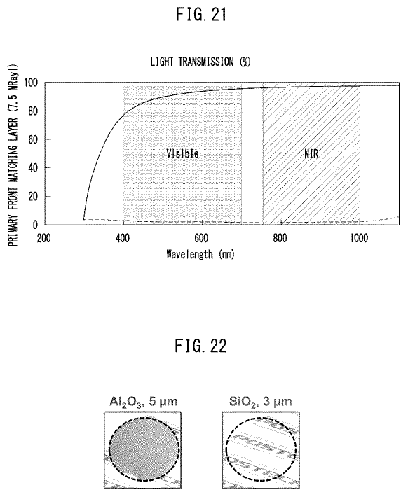

FIG. 21 is a graph showing the light transmission as a function of the wavelength of the primary front matching layer fabricated by the TUT fabricating method of the present embodiment. FIG. 22 is a diagram showing the light transmission of a composite that may be adopted in the front matching layer of the TUT of the present embodiment and a composite of a comparison example.

FIGS. 21 and 22 show that the primary front matching layer (refer to the right diagram in FIG. 22) formed of the first silicon oxide (SiO₂) composite to have a characteristic of an acoustic impedance of 7.5 MRayl is found to exhibit light transmission of about 80 to 95% in the visible light region of a wavelength of 400 to 750 nm and light transmission of about 95 to 99% in the near-infrared (NIR) region of a wavelength of 750 to 1000 nm. It is to be noted that the first aluminum oxide (Al₂O₃) composite (refer to the left diagram in FIG. 22), which is an opaque composite, is denoted by the dotted line at the bottom of FIG. 22.

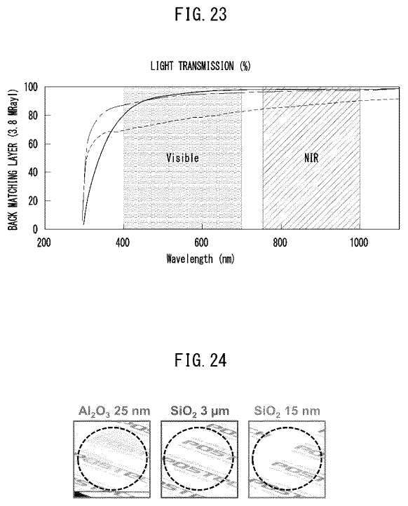

FIG. 23 is a graph showing the light transmission as a function of the wavelength of a back matching layer fabricated by the TUT fabricating method of the present embodiment. Further, FIG. 24 is a diagram for describing the light transmission of various composites that may be adopted in the back matching layer of the TUT of the present embodiment.

FIGS. 23 and 24 show that the back matching layer (refer to the left diagram in FIG. 24) formed of the second aluminum oxide (Al₂O₃) composite to have a characteristic of an acoustic impedance of 3.8 MRayl exhibits light transmission of about 70 to 80% in the visible light region of a wavelength of 400 to 750 nm and light transmission of about 80 to 90% in the near-infrared region of a wavelength of 750 to 1000 nm as denoted by the dotted line in FIG. 23.

The back matching layer (refer to the middle diagram in FIG. 24) formed of the first silicon oxide (SiO₂) composite to have a characteristic of an acoustic impedance of 3.8 MRayl exhibits light transmission of about 80 to 98% in the visible light region and light transmission of about 98 to 99% in the near-infrared region as denoted by the solid line in FIG. 23.

The back matching layer (refer to the right diagram in FIG. 24) formed of the second silicon oxide (SiO₂) to have a characteristic of an acoustic impedance of 3.8 MRayl exhibits light transmission of 86 to 97% in the visible light region and light transmission of 97 to 99% in the near-infrared region as denoted by the dash-dotted line in FIG. 23, similar to the case of the first silicon oxide composite.

According to the present embodiment, unlike the composites made by conventional methods, the TUT transparent matching layer made by adjusting the refractive index and acoustic performance of light is found to exhibit high light transmittance for the visible and infrared rays.

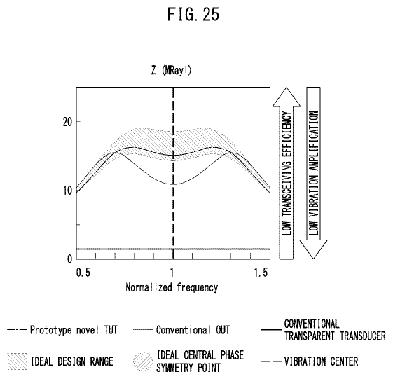

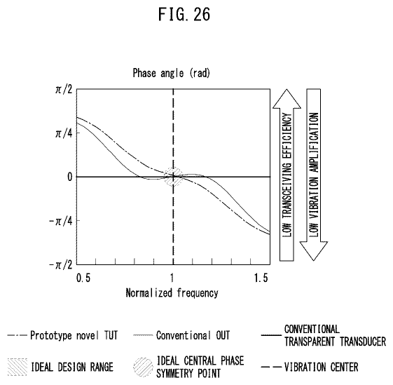

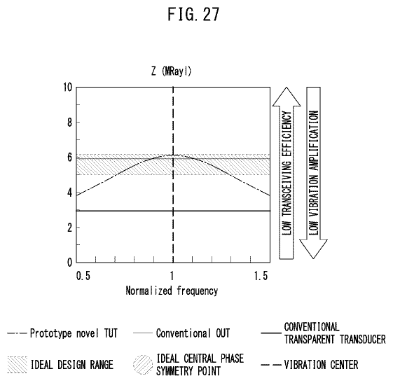

FIG. 25 is a graph for describing the effective acoustic impedance magnitude on the forward side of the present embodiment and comparison examples. FIG. 26 is a graph for describing the phase angle of the effective acoustic impedance on the forward side of the present embodiment and comparison examples. Further, FIG. 27 is a graph for describing the effective impedance on the backward side of the present embodiment and comparison examples.

The measurement results based on the TUT structure of the present embodiment (refer to FIG. 7) are denoted by the solid line, the measurement results of the comparison example 1 based on the opaque ultrasound transducer structure (refer to FIG. 8) are denoted by the dash-dotted line, and the measurement results of the comparison example 2 based on the conventional transparent ultrasound transducer structure (refer to FIG. 9) are denoted by the dash-double dotted line.

FIG. 25 shows the distribution of the acoustic impedance formed along the resonance center frequency on the forward side based on the TUT structure of the present embodiment. In other words, the magnitude of the forward effective acoustic impedance Z of the prototype novel TUT of the present embodiment is positioned symmetrically around the resonance center frequency within the hatch region of the ideal design range indicated by two dotted lines. The resonance center frequency is the center of vibration denoted by the vertical dotted line and expressed as a normalized frequency with a magnitude of 1. In this way, the TUT of the present embodiment is found capable of achieving optimal performance by the effective acoustic impedance satisfying the ideal design range.

On the other hand, the conventional OUT of the comparison example 1 is found to have a relatively low transceiving efficiency and a relatively low vibration amplitude near the vibration center compared to the TUT of the present embodiment.

Further, the conventional transparent transducer of the comparison example 2 is found to have a very low-sized forward effective acoustic impedance Z, thus a relatively very low transceiving efficiency and a very low vibration amplitude.

In particular, as shown in FIG. 26, the phase angle of the forward effective acoustic impedance has a zero-phase characteristic at the resonance frequency of the ideal central phase symmetry point, such as the hatched region denoted by a dotted circle at the center. In other words, the phase angle of the acoustic impedance of the present embodiment has a non-changing form, but the comparison example 1 (conventional OUT) has a fluctuating form at the phase angle changes near the resonance frequency and the conventional transparent transducer of the comparison example 2 has a horizon shape in which the phase angle is fixed at 0 (rad) regardless of the operating frequency.

In addition, FIG. 27 shows the distribution of the acoustic impedance formed along the resonance center frequency on the backward side based on the prototype novel TUT structure of the present embodiment. In other words, the magnitude of the backward effective acoustic impedance Z of the TUT of the present embodiment is positioned in the ideal design range near the resonance center frequency within the hatch region of the ideal design range denoted by two dotted lines and expressed as the normalized frequency 1, and the acoustic impedance significantly decreases when deviating from the resonance center frequency. In this way, the TUT of the present embodiment may be found effectively absorbing the acoustic impedance through the back acoustic absorption layer.

According to the configuration described above, both the front and back impedances fall short of the ideal magnitude in the conventional transparent transducer, resulting in performance degradation, but the TUT of the present embodiment was found partially similar to the conventional opaque transducer (OUT) and its acoustic impedance and phase angle were found positioned within the ideal design range.

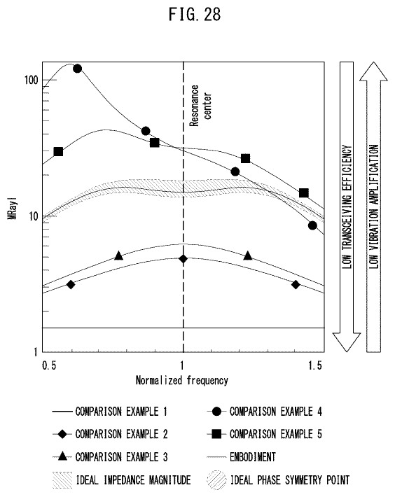

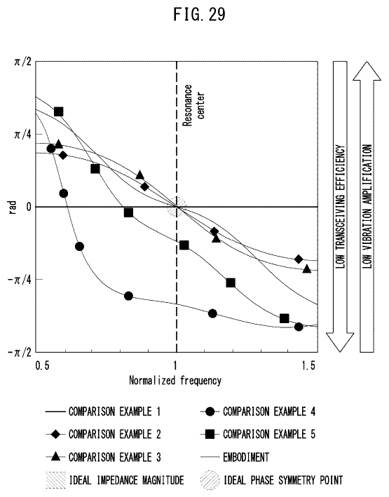

Further description of the impedance difference between the present embodiment and other conventional comparison examples with reference to FIGS. 28 and 29 is as follows.

FIG. 28 is a graph showing a comparison between the performances of each TUT based on the measured forward effective acoustic impedance magnitudes in the present embodiment and comparison examples. FIG. 29 is a graph showing a comparison between the performances of each TUT based on the measured forward effective impedance phases in the present embodiment and comparison examples.

As shown in FIG. 28, the acoustic impedance of the TUT of the present embodiment is positioned in the ideal impedance magnitude range denoted by the hatched region and has a symmetrical shape around the resonance center. The ideal impedance has about 10 MRayl at normalized frequencies of 0.5 and 1.5 and has a magnitude of about 15 MRayl to about 20 MRyal in the range of normalized frequencies of about 0.7 to 1.3 including the resonance center frequency.

On the other hand, the comparison example 1 has a constant and low acoustic impedance. The comparison example 2 or comparison example 3 has a symmetrical shape about the resonance center but has a relatively very low acoustic impedance with no section included in the ideal impedance magnitude region. The comparison example 4 exhibits a very high acoustic impedance, about 4 to 10 times the ideal impedance, at frequencies lower than the resonance center frequency and has a gradually decreasing impedance as the frequency increases from the resonance center frequency. Further, the comparison example 5 has a high acoustic impedance, about 2 to 4 times the ideal impedance magnitude, and an asymmetrical shape around the resonance center.

In addition, as shown in FIG. 29, the phase angle of the forward effective acoustic impedance of the present embodiment has a zero-phase characteristic at a resonance frequency of the ideal central phase symmetry point. However, the phase angle of the comparison examples 1 to 5 are found not only asymmetrical but to substantially deviate from the ideal design.

The comparison example 1 described above is one of the typical conventional TUTs, the comparison example 2 is a parylene matching TUT, the comparison example 3 is an epoxy lens TUT, the comparison example 4 is an N-SF11 hard glass lens TUT, and the comparison example 5 is a thick glass matching TUT.

In this way, the impedance magnitude and phase symmetry point of the conventional transparent ultrasound transducer are significantly off from the ideal design region, but the transparent ultrasound transducer of the present embodiment is found to implement the impedance magnitude and phase conditions within the ideal region.

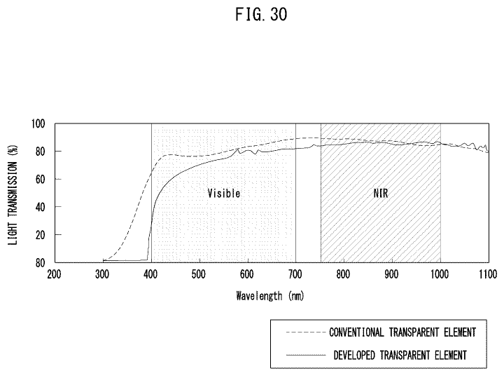

FIG. 30 is a graph showing a comparison between light transmissions of a developed transparent element (embodiment) fabricated by the TUT fabricating method of the present embodiment and a conventional transparent element (comparison example).

FIG. 30 shows that the light transmission of the TUT (refer to FIG. 7) of the present embodiment is found practically no different or not much different from the light transmission of the conventional transparent ultrasound transducer (refer to FIG. 9) in both the visible light and near-infrared regions.

In other words, the TUT of the present embodiment may exhibit excellent performance with stable and highly reliable transceiving efficiency and vibration amplification while maintaining light transmission.

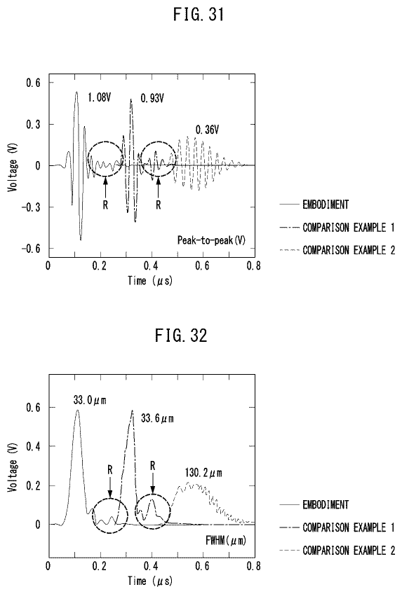

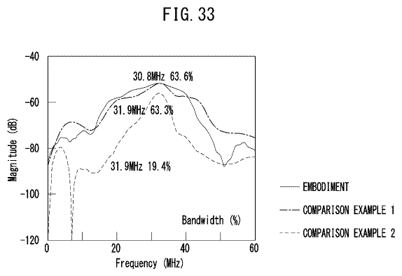

FIG. 31 is a graph showing a comparison between the peak-to-peak voltages in the pulse-echo response waveform of the present embodiment and comparison examples. FIG. 32 is a graph showing a comparison between full-width-at-half-maximum (FWHW) in the pulse-echo response waveform of the present embodiment and comparison examples. Further, FIG. 33 is a graph showing echo frequency analysis results of the present embodiment and comparison examples.

FIGS. 31 to 33 show that the acoustic transceiving capability of the TUT of the present embodiment is found better than the conventional transparent ultrasound transducer and similar to the opaque ultrasound transducer according to the comparison of the acoustic wave echo capability performance based on the design simulation and experimental results between the TUT of the present embodiment, the conventional opaque transducer of the comparison example 1, and the conventional transparent transducer of the comparison example 2.

In other words, as shown in FIG. 31, after the experiment on the TUT of the present embodiment starts, a pulse of 1.08 V generated at 0.1 μs and a residual echo R generated immediately thereafter may be observed. Similarly, after the experiment on the conventional opaque ultrasound transducer starts, a pulse of 0.93 generated at 0.3 μs and a residual echo R generated immediately thereafter may be observed. On the other hand, only a pulse of up to 0.36 V may be found oscillating in the case of the conventional transparent ultrasound transducer.

In addition, as shown in FIG. 32, comparison results of the full-width-at-half-maximum (FWHM) of the pulse echo response waveforms are found similar to the experimental results of FIG. 26.

In addition, as shown in FIG. 33, in the echo frequency analysis results, the TUT of the present embodiment is also found to have an echo frequency magnitude similar to that of the opaque ultrasound transducer of the comparison example 1 in each bandwidth, and this performance is found excellent compared to the conventional transparent ultrasound transducer of the comparison example 2.

In this way, test results indicate that the TUT of the present embodiment exhibits actual acoustic transceiving capability higher than that of the conventional transparent ultrasound transducer and similar to that of the opaque ultrasound transducer.

According to the configuration described above, the issue of the significantly inferior acoustic performance of the transparent ultrasound transducer compared to the acoustic performance of the conventional opaque ultrasound transducer may be resolved. In other words, the conventional technical issue arising from the acoustic impedance mismatch between a hard piezoelectric crystal and a soft loading medium may be resolved through novel transparent matching and acoustic absorption materials that may be loaded on the surface of the piezoelectric crystal without a bonding gap and that have a suitable acoustic impedance.

In addition, the method for fabricating the TUT of the present embodiment may be automated by a control device controlling the ultrasound transducer fabricating equipment or a computing device performing functions of such control device. In this case, the control device or computing device may store software or program commands used to implement the fabricating method referred to in the embodiments described above.

The operations of the method according to the exemplary embodiment of the present disclosure can be implemented as a computer readable program or code in a computer readable recording medium. The computer readable recording medium may include all kinds of recording apparatus for storing data which can be read by a computer system. Furthermore, the computer readable recording medium may store and execute programs or codes which can be distributed in computer systems connected through a network and read through computers in a distributed manner.

The computer readable recording medium may include a hardware apparatus which is specifically configured to store and execute a program command, such as a ROM, RAM or flash memory. The program command may include not only machine language codes created by a compiler, but also high-level language codes which can be executed by a computer using an interpreter.

Although some aspects of the present disclosure have been described in the context of the apparatus, the aspects may indicate the corresponding descriptions according to the method, and the blocks or apparatus may correspond to the steps of the method or the features of the steps. Similarly, the aspects described in the context of the method may be expressed as the features of the corresponding blocks or items or the corresponding apparatus. Some or all of the steps of the method may be executed by (or using) a hardware apparatus such as a microprocessor, a programmable computer or an electronic circuit. In some embodiments, one or more of the most important steps of the method may be executed by such an apparatus.

In some exemplary embodiments, a programmable logic device such as a field-programmable gate array may be used to perform some or all of functions of the methods described herein. In some exemplary embodiments, the field-programmable gate array may be operated with a microprocessor to perform one of the methods described herein. In general, the methods are preferably performed by a certain hardware device.

The description of the disclosure is merely exemplary in nature and, thus, variations that do not depart from the substance of the disclosure are intended to be within the scope of the disclosure. Such variations are not to be regarded as a departure from the spirit and scope of the disclosure. Thus, it will be understood by those of ordinary skill in the art that various changes in form and details may be made without departing from the spirit and scope as defined by the following claims.

1-20. (canceled)

21. A transparent ultrasound transducer comprising:
a piezoelectric unit including a piezoelectric element having a first transparent electrode formed on a front surface and a second transparent electrode formed on a back surface; and
a first front matching layer formed of a composite including a ceramic-epoxy resin mixture, the front matching layer having an acoustic impedance of 7 to 9 MRayl, and being directly cured on the front surface of the piezoelectric element without a bonding gap.

22. The transparent ultrasound transducer of claim 21, wherein a forward effective acoustic impedance at a front side of the piezoelectric element including the first front matching layer and biological tissue, is configured to have a value within a range of 10 to 20 MRayl at a resonance center frequency.

23. The transparent ultrasound transducer of claim 21, wherein a magnitude of a forward effective acoustic impedance of the transparent ultrasound transducer is positioned symmetrically around the resonance center frequency.

24. The transparent ultrasound transducer of claim 21, wherein the acoustic impedance of the composite is configured to be determined by a volume fraction of ceramic particles and bulk modulus and shear modulus of each of the ceramic particles and the epoxy resin.

25. The transparent ultrasound transducer of claim 21, wherein the first front matching layer is formed by spin-coating or spray-coating.

26. The transparent ultrasound transducer of claim 21, wherein the front matching layer is a quarter-wavelength thick with respect to the resonance center frequency.

27. The transparent ultrasound transducer of claim 21, further comprising a second front matching layer formed of a transparent material on the first front matching layer, the second front matching layer having a refractive index similar to that of the first front matching layer.

28. The transparent ultrasound transducer of claim 21, further comprising an acoustic absorption layer formed on the back of the piezoelectric unit, the acoustic absorption layer including a back matching layer that is formed of the composite, forms a back side boundary of the piezoelectric unit and absorbs an acoustic energy traveling towards the back of the piezoelectric unit.

29. The transparent ultrasound transducer of claim 28, wherein an acoustic impedance of the back matching layer is 3 to 6 MRayl.

30. The transparent ultrasound transducer of claim 28, wherein the first front matching layer or the back matching layer comprises side edges formed by cutting corners to expose the first transparent electrode.

31. The transparent ultrasound transducer of claim 21, further comprising a conductive ring member disposed between the back matching layer and the back polymer layer; and
a case that accommodates a stacked structure of the front polymer layer, the front matching layer, the back matching layer, the back polymer layer, and the conductive ring member.

32. A method of fabricating a transparent ultrasound transducer, the method comprising:
providing a piezoelectric element having first and second transparent electrodes;
forming a front matching layer of a transparent composite including a silica-epoxy resin mixture, the front matching layer having an acoustic impedance of 7 to 9 MRayl; and
curing the front matching layer directly on the front surface of the piezoelectric element without a bonding gap;
wherein the front matching layer is directly formed on the front surface of the piezoelectric element without a bonding gap.

33. The method of claim 32, wherein the front matching layer is spin-coated or spray-coated using a composite containing silica (SiO₂) micro-particles with a particle diameter of less than 10 μm.

34. The method of claim 32, further comprising forming a front polymer layer of a transparent polymer material on the front matching layer, the front polymer layer having a refractive index similar to that of the front matching layer.

35. The method of claim 32, further comprising forming a back matching layer on the back surface of the piezoelectric element, the back matching layer being formed of the transparent composite, forming a back side boundary of the piezoelectric unit, and absorbing an acoustic energy traveling towards the back of the piezoelectric unit.

36. A transparent ultrasound transducer comprising:
a piezoelectric unit including a piezoelectric element having a first transparent electrode formed on a front surface and a second transparent electrode formed on a back surface; and
a back matching layer formed of a composite including a ceramic-epoxy resin mixture, the back matching layer having an acoustic impedance of 3 to 6 MRayl, being directly cured on the front surface of the piezoelectric element without a bonding gap, and absorbing acoustic energy traveling towards the back of the piezoelectric unit.

37. The transparent ultrasound transducer of claim 36, wherein the acoustic impedance of the composite is configured to be determined by a volume fraction of ceramic particles and bulk modulus and shear modulus of each of the ceramic particles and the epoxy resin.

38. The transparent ultrasound transducer of claim 36, wherein the back matching layer is a quarter-wavelength thick with respect to a transmission wavelength, and the piezoelectric unit has a thickness of approximately half of the transmission wavelength.

39. The transparent ultrasound transducer of claim 36, further comprising a back polymer layer disposed on the back matching layer, the back matching layer and the back polymer layer are configured to form an acoustic absorption layer that forms a back side boundary of the piezoelectric unit and absorbs acoustic energy traveling towards the back of the piezoelectric unit.

40. The transparent ultrasound transducer of claim 36, further comprising a first front matching layer formed of the composite, the front matching layer having an acoustic impedance of 7 to 9 MRayl, and being directly cured on the front surface of the piezoelectric element without a bonding gap.
